(19) United States
(12) Patent Application Publication
(10) Pub. No.: US 2011/0052909 A1
(43) Pub. Date: Mar. 3, 2011

(54) DEVICE FOR THERMOHYDRAULIC APPLICATIONS WITH IMPROVED WATER SOFTENING PROPERTIES, LOWER RELEASE OF HEAVY METALS, AND RELATIVE METHOD OF MANUFACTURING

(75) Inventor: Roberto Canton, Trezzano Rosa (IT)

(73) Assignee: MOMA S.R.L., Dalmine (IT)

(21) Appl. No.: 12/989,211

(22) PCT Filed: Apr. 23, 2009
(86) PCT No.: PCT/EP09/54913

§ 371 Date: Nov. 8, 2010

(30) Foreign Application Priority Data
Apr. 24, 2008 (IT) MI2008A000773

(51) Int. Cl. B32B 27/00; C23C 16/50; C23C 16/44; C23C 4/00; C08G 77/00; C08F 30/08

(52) U.S. Cl. 428/336; 428/448; 427/578; 427/535; 528/10; 526/279

(57) ABSTRACT

Device for thermohydraulic applications wherein at least one portion of one surface destined for contact with water is coated with a film comprising at least one layer of a material applied by means of plasma phase polymerization of one or more monomers containing silicone. The relative method for obtaining the device comprises the following phases: to precondition a device for thermohydraulic applications within a vacuum chamber; to bring the vacuum chamber to pressure conditions between 0.01 and 100 Pa; to introduce a first gaseous mixture comprising at least a monomer containing silicone into said chamber; to bring said monomer containing silicone to the plasma state by means of an electromagnetic wave; to maintain the ionization conditions for a period of time sufficient to permit the deposit of a layer of a polymer containing said monomer on at least a portion of a surface of said device.

The present invention relates to a device for thermohydraulic applications having improved water softening properties and lower release of heavy metals, and to a method for obtaining said device. For the purpose regarding the aims of the present invention, the term device for thermohydraulic applications refers to the components used in the realisation of hot water or steam production systems for commercial, industrial and domestic use. For example, this includes devices for thermohydraulic applications such as delivery pipes, elements, valves, boilers and similar items used in applications such as: systems for producing hot water or steam for hot beverages in automatic and semi-automatic machines, for both commercial and domestic purposes, household appliances such as irons, humidifiers, kettles, dish-washers, washing machines; floor washers and similar appliances using hot water or steam, whether domestic or industrial; systems in which hot water or steam is used for personal hygiene; water heating systems for industrial use.

It is known that the large amounts of solid deposits which form during water heating processes depend on many factors: temperature, saline concentration, pH, water flow rate, presence of inhibitors, roughness and chemical composition of the substrate, as well as other conditions that contribute towards making the phenomenon more complex. In fact, drinking water contains a large number of species that cause the deposit of solid substances such as: calcium and magnesium ions, soluble silicate compounds, ferrous ions, and others. This deposit, which will be referred to hereafter by the term “limestone”, is mainly caused by calcium and magnesium salts that precipitate onto the warm walls of the various hot water or steam generating systems. The deposits that form are prevalently: calcium salts (such as carbonates, phosphates, sulphates), of magnesium, silica or silicates, ferrous oxides and hydroxides, zinc phosphates and hydroxides.

Deposit and lime scale are caused by water containing dissolved salts, such as those found in drinking water, and the phenomenon begins when part of the water is evaporated, such as during heating action.

The scaling that is formed in delivery pipes, for example, and on heating elements, in valves, and on boiler walls, can actually provoke a block caused by continuous limestone formation which gradually reduces the space through which the hot water or steam must pass. When this occurs, the blocked systems or components shut off and they must be replaced or cleaned. The forming and growth of this lime deposit results as being extremely adherent to the surface on which it forms, thus provoking total clogging of holes in valves, or openings in boiler bodies, as well as element malfunction. It is a fact that with time, the by-product of water heating contributes towards preventing the use of the hot water or steam production systems.

At present the only method for eliminating deposit and for restoring the operating function of hot water or steam delivery requires mechanical cleaning action, or more often, the use of an acid solution to dissolve the deposits.

In order to increase the working life of these systems, often the inlet water is treated using methods to reduce the water hardness or to prevent the forming of limestone, but these systems do not eliminate the problem and contribute towards increasing the complexity and the cost of the total system, thus also requiring regular maintenance interventions.

As can be seen from the explanations provided above, conventionally known devices for thermohydraulic applications present a range of drawbacks for which several solutions have been proposed, but without fully satisfactory results.

On the basis of these considerations, the main aim of the present invention is to provide a device for thermohydraulic applications that is able to overcome the aforesaid drawbacks.

Within this aim, an object of the present invention is to provide a device for thermohydraulic applications which is equipped with improved water softening properties.

A further object of the present invention is to provide a device for thermohydraulic applications, which is highly reliable, relatively easy to produce, and at competitive cost.

This aim, as well as these and other objects which will be described in more detail further on, is achieved by means of a device for thermohydraulic applications, according to the invention, characterised in that at least one portion of its surface destined for contact with water, is coated with a film comprising at least one layer of a material applied using the plasma phase polymerization of one or more monomers containing silicon.

In a further aspect, the present invention also relates to a method for the preparation of a device for thermohydraulic applications having improved water softening properties; the method according to the invention is characterised in that it comprises the following phases:

a) positioning the device for thermohydraulic applications within a vacuum chamber;

b) bringing the vacuum chamber to pressure conditions ranging between 0.01 and 100 Pa;

c) introducing a first gaseous mixture comprising at least one monomer containing silicone into said chamber;

d) bringing said monomer containing silicone to the plasma state by means of an electromagnetic wave;

e) maintaining ionisation conditions for a sufficient period of time to permit the application of a layer of polymer containing silicone on at least one portion of a surface of said device.

The device and the method according to the invention, help to overcome the problems and the drawbacks present in known type devices. In other words, experiments were performed by applying a specific coating, produced by means of particular technology on at least certain portions of the surface of the device, thus reducing the limestone formation on said surfaces to a considerable extent, with obvious benefits from the viewpoint of general use and useful work life of the device in question, as well as for any systems in which the device in mounted.

Preferably said monomers containing silicone are chosen among: hexamethyldisiloxane, tetramethylsilane, tetraethoxysilane, 3-glycidoxypropyltrimethoxysilane, phenyltrimethoxysilane, dimethoxymethylphenylsilane, tetraethoxysilane, 3-methacryloxypropyltrimethoxysilane, triethoxyvinylsilane, octamethyl cyclotetrasilane, methyltriethoxysilane, di-ethoxymethyl phenylsilane, tris(2-methoxyethoxy)vinylsilane, phenyltriethoxysilane, dimethoxydiphenylsilane, tetramethyldisilazane, hexamethyldisilazane, diethoxymethylsilane, ethyltrimethoxysilane, tetramethoxysilane, methyltrimethoxysilane, dimethoxy-dimethylsilane, tetramethyldisiloxane, tetramethyl-ethoxysilane, methyltrimethoxysilane, dimethyldimethoxy-silane, trimethylmethoxysilane, tetraethylsilane and silane.

Furthermore, said monomers containing silicone are preferably gaseous organosilicone monomers in pressure conditions between 0.01 and 100 Pa.

Preferably, the polymerized material applied on the surface of the device has formula:

SiOxCyHzNw

where 0.1≦x≦10, 0≦y≦10, 0≦z≦10, 0≦w≦10.

According to a specific embodiment of the device according to the invention, said film, applied using plasma phase polymerization of one or more monomers containing silicon, has a single composition of a type similar to natural quartz, or SiO2, or of a silicone type such as SiOxCyHzNw

According to a specific embodiment of the device according to the invention, said film comprises a plurality of layers of materials of different compositions applied using plasma phase polymerization of one or more monomers containing silicon. For example, said film can comprise a first layer of formula SiOx where x=2, and a second layer of formula SiOxCyHzNw.

The thickness of the layer, whether a single or multi-layer composition, of material applied to the surface of the device can vary according to requirements. It has been proved that thicknesses between 0.01 and 10 μm generally guarantee good results in terms of anti-limestone properties.

The devices according to the invention can be prepared through deposition of specific monomers in the plasma phase.

According to the technique of polymerization in plasma phase, also known as PECVD technique (plasma enhanced chemical vapor deposition), in other words, the deposition through chemical reaction by means of plasma; a main reagent (monomer), possibly mixed with other gases, is brought to the plasma state at a pressure of approximately 100 Pa and 0.01 Pa. In these conditions, the monomer will split into fragments and bond with other molecules to form the polymer.

The low pressure polymerization process of an organic or inorganic film occurs by bringing the reagent gases to the plasma state; for the aims of the present invention, the term plasma refers to an excited gas, and therefore composed of neutral species, and of electrons and ions not bonded with one another, but as a whole, neutral from an electrical viewpoint.

According to the present invention, with the PECVD technique it is possible to deposit a film comprising one or more very fine layers of SiOxCyHzNw composition on at least part of the surfaces of the devices that are destined to enter into contact with the heated water. The terms x, y, z, and w can vary according to the chemical characteristics that may be required and which range from the inorganic to silicone compounds. Thanks to the deposit of these layers it is possible to achieve a surface that reduces adhesion to a large extent, and therefore also reduces the formation, growth and deposit of limestone.

The monomers used for the deposition reaction are silicone based organic and inorganic compounds. Typical silicone based organic compounds that can be used for practical realisation of the present invention were selected from the group comprising all the organosilicone compounds containing silicone, oxygen, carbon, hydrogen and possibly nitrogen which are gaseous in a pressure interval between 100 Pa and 0.01. For example, these can include: hexamethyldisiloxane, tetramethylsilane, tetraethoxysilane, 3-glycidoxypropyl trimethylsilane, phenyltrimethoxysilane, dimethoxy-methylphenylsilane, tetraethoxysilane, 3-metacryl-oxypropyltrimethoxysilane, triethoxyvinylsilane, octamethyl cyclotetrasilane, methyltriethoxysilane, di-ethoxymethyl phenylsilane, tris(2-methoxyethoxy)vinyl-silane, phenyltriethoxysilane, dimethoxydiphenylsilane, tetramethyldisilazane, hexamethyldisilazane, diethoxymethyl-silane, ethyltrimethoxysilane, tetramethoxysilane, methyltrimethoxysilane, dimethoxydimethylsilane, tetramethyldisiloxane, tetramethylethoxysilane, methyltrimethoxysilane, dimethyldimethoxysilane, trimethylmethoxysilane, tetraethylsilane and silane.

The silicone monomer or monomers are introduced into the reaction chamber, possibly with the addition of some oxygen. The ratio between the partial pressures of the reagent gases will determine the chemical type of the film created. By increasing the amount of oxygen in relation to the monomer, there is a proportional reduction in the carbon content of the coating that is continued until it is excluded completely (e.g.: formation of SiO2).

By varying the content of the monomers and/or their relative proportions and/or their proportion with any oxygen which may be present, for example by changing the ratio of the partial pressure of the organosilicone gas of the oxygen, it is possible to even create several consecutive superimposed layers, each of which can present a respective x, y, z, w index.

The method according to the invention represents an advantageous application in the coating of those devices that need to be protected against the formation of limestone, such as in boilers, heating elements, and valves. The anti-limestone treatment can be applied to one or all of the sensitive components according to specific requirements.

Thermohydraulic devices can be produced using components in metal or alloy materials, just as they can be produced from polymers including rubber materials. It was proved that the layer of polymer material of which the components described are composed, can be deposited on any type of material from which the described components are made, obtaining the same beneficial effect.

The process composed of the application or deposit of a covering film comprising one or more polymer layers is performed in a vacuum chamber, in other words, a chamber which is in communication with a vacuum source, typically one or more vacuum pumps or some other appropriate suction means which is able to create a depression of 0.01-100 Pa within the chamber.

The one or more devices requiring anti-limestone properties are placed inside the chamber. The monomers, possibly mixed with oxygen, are brought to the plasma state supplying energy through an antenna, for example; typically the energy is supplied in the form of electromagnetic energy at high frequency such as 13.56 MHz, or low frequency at approximately KHz (low frequency) or at microwave frequency, or through direct current (DC), using a radiofrequency generator of any appropriate type.

When the gases are excited and brought to the physical plasma state, ionisation occurs forming highly reactive species. Organosilicone gas plasmas, if possibly mixed with oxygen, have reaction by-products CO2 and H2O and possible non-reacted monomer.

The polymer obtained using the PECVD technique develops in proximity to the surface of the devices introduced into the processing chamber. A very fine film forms on the exposed surface or surfaces of the product, with a thickness between a few dozen nanometres and a few millimetres, and which, according to the process conditions, can assume a composition similar to natural quartz or a silicone type, and therefore with a carbon content in the coating composition, or by modifying the ratio between the organosilicone and the oxygen each time, multi-layer films can be obtained.

The formation of a multi-layer type coating can be obtained without interrupting the plasma formation, but by modifying the ratio of the reagents during the formation of the coating.

According to a preferred embodiment of the present invention, before the application of the film (whether single or multi-layer) on the device using the aforementioned plasma method, the device or a surface part must be pre-treated using a so-called “plasma grafting” process.

The term “plasma grafting” refers to a process wherein oxidation reaction occurs on at least one portion of the product surface. For the aims of the present invention the expression “plasma grafting” refers to a process of chemical group application, formed during plasma phase, on the surface or part of the surface to be successively coated using the PECVD technique. According to the type of plasma employed, it is possible to apply oxydril, amminic or similar groups onto the product.

The effect obtained with plasma grafting pre-treatment is dual: thanks to its oxidative capacity, by eliminating any organic micro-contaminants which split and evaporate; and by oxidising the surface, thus preparing the substrate for the PECVD deposit. In other words any pre-treatment using plasma grafting can provide improved anchoring adhesion between the substrate and the successive film obtained using the PECVD technique.

The gases used for this process can be any of the following: Oxygen, Air, Nitrogen, Carbon dioxide, Nitrogen oxide, or in any case, all gas plasmas able to provoke oxidation reactions on the surface of the device.

Plasma grafting pre-treatment can occur in the same chamber used for the film deposit using PECVD techniques. In this case the film can be deposited immediately after the pre-treatment, in other words, without interrupting the plasma formation and introducing into the chamber the reagents necessary for the coating layer formation.

Therefore, it is possible to pre-treat a product using the plasma grafting process, coating it successively with at least one film of varying thickness, by using the polymerization system in plasma phase. In a similar manner, in cases where pre-treatment is not performed, the effect can be obtained by placing the device in a vacuum chamber and once the required vacuum level has been reached (such as between 0.01 Pa and 100 Pa), and by introducing the main reagent (monomer) which is gaseous in these conditions and temperature. This can possibly be mixed with other gases such as oxygen, for example. The gases are successively brought to the plasma state by means of an electromagnetic wave that provokes the coating formation which is deposited in the form of a very fine layer of between 0.01 and 10 μm on the surface of the product.

Preferably the reaction times in the plasma formation phases on the device vary between 1 minute and 3 hours according to the desired thickness of the film to be deposited.

### EXAMPLES

Anti-limestone performance according to the present invention was assessed on a range of devices controlling the amount and characteristics of the limestone adhesion on a system for continuous hot water delivery. All the parts of the delivery system in contact with the hot water were treated with the object of the present invention, in other words: an electric element (incoloy material), a boiler body (brass material), a boiler top cover (brass material), electrovalve units for distribution control (brass material), electrovalve closing pistons (brass and steel material) with admitted seals, water canalisation systems (brass material). No water softener filters were applied to the system in order to assess the system performance in the most critical conditions.

Furthermore, parallel testing was carried out on samples with different levels of surface finish carried out before the application of the protective anti-limestone layer according to the present invention. Three types of finish were tested in particular: acid pickling, shot-blasting, or plain degreasing using surface active products.

The tests were performed both on a sample coated with a single, basically homogenous layer, as well as a sample with two layers having a variable composition; In addition, a non-treated sample was also assessed for comparative purposes.

In the experiment described, the aforesaid components were treated with the coatings object of the present invention, in the following operating conditions:

### Example 1

### Single Layer Coating

Phase 1. Pre-treatment with Plasma Grafting
a. Gas type: O2
b. Plasma generation frequency: 13.56 MHz
c. Plasma generation power: 600 watt
d. Treatment duration: 2 minutes;

Phase 2. Coating with anti-limestone film—SiOx type (where x=2)
a. Gas type: O2 and HMDSO
b. Flow ratio O2/HMDSO=11.5
c. Plasma generation frequency: 13.56 MHz
d. Plasma generation power: 600 watt
e. Treatment duration: 60 minutes.

### Example 2

### Multi-Layer Coating

Phase 1. Pre-treatment with Plasma Grafting
a. Gas type: O2
b. Plasma generation frequency: 13.56 MHz
c. Plasma generation power: 600 watt
d. Treatment duration: 2 minutes;

Phase 2. First coating with anti-limestone film—SiOx type (where x=2)
a. Gas type: O2 and HMDSO
b. Flow ratio: O2/HMDSO=11.5
c. Plasma generation frequency: 13.56 MHz
d. Plasma generation power: 600 watt
e. Treatment duration: 30 minutes;

Phase 3. Second coating with silicone type anti-limestone film
a. Gas type: O2 and HMDSO
b. Flow ratio: O2/HMDSO=2.5
c. Plasma generation frequency: 13.56 MHz
d. Plasma generation power: 600 watt
e. Treatment duration: 30 minutes

The characteristics of the test systems were as follows:

1. Internal volume of the boiler: 157 cm3

2. Overall length of the heating element: 65 cm

3. Heating element diameter: 8.5 mm

4. Drinking water with water hardness at inlet of 15° f.

5. Average water temperature at outlet: 75° C.

6. Average water temperature in boiler: 103° C.

The test consisted of the delivery of hot water in amounts equal to 50 cm3 and 90 cm3 in continuous succession. The boiler operating conditions were monitored at the following delivery intervals: 10,000, 20,000, 30,000, 45,000, 65,000, inspecting the various components and attempting to remove the limestone with a water spray jet to control adhesion to the substrate.

The results were as follows:

10.000 Delivery Interval

Reference example (Non-coated devices): The limestone adhered strongly to all components (above all on the heating element) and could not be removed with water. The orifice sections were reduced because of limestone deposit. Limestone also adhered to closing pistons including the rubber seal parts. The system operated correctly.

Example 1 (devices with a single layer coating): the amount of limestone was considerably inferior in comparison to the non-treated devices, and where it was present, it was easily removed with water, showing the original surface; the valve orifices were clear. There were no signs of limestone on pistons and rubber seals. The system operated correctly.

Example 2 (devices with multi-layer coating): the amount of limestone was considerably inferior compared to the non-treated devices, and where it was present, it was easily removed with water, showing the original surface ; the valve orifices were clear. There were no signs of limestone on pistons and rubber seals. The system operated correctly.

20.000 Delivery Interval

Reference example (Non-coated devices): the system shut down because of limestone occlusion on certain valve orifices. The heating element became a single solid block of limestone attached to the boiler. The test was interrupted. It was impossible to remove the limestone from any components without the use of acid chemicals. The system was no longer operational.

Example 1 (devices with a single layer coating): the amount of limestone was greater compared to the test after the 10.000 delivery interval. A larger amount of limestone was observed, above all on the heating element, and was strongly adherent. In other parts, where present, the limestone was easily removed with water, showing the original surface; the valve orifices were clear. There were no signs of limestone on pistons and rubber seals. The system operated correctly.

Example 2 (devices with multi-layer coating): the amount of limestone was the same as after the 10.000 delivery interval test. There was only a small increase of limestone on the heating element. In any case, where it was present it was easily removed with water, showing the original surface; the valve orifices were clear. There were no signs of limestone on pistons and rubber seals. The system operated correctly.

30.000 Delivery Interval

Example 1 (devices with a single layer coating): the amount of limestone was greater than the test after the 20.000 delivery interval. There were signs of limestone formation on the heating element and on the boiler body, resistant enough that they could not be removed with water alone. In the remaining parts the limestone was easily removed with water showing the original surface; the valve orifices were clear. There were no signs of limestone on pistons and rubber seals. The system operated correctly.

Example 2 (devices with multi-layer coating): the amount of limestone was substantially the same as the test after the 20.000 delivery interval, except on the heating element where there was a larger formation of limestone, part of which could not be removed with water, but which did not compromise the system operation. In the remaining parts, where present, the limestone was easily removed with water showing the original surface; the valve orifices were clear. There were no signs of limestone on pistons and rubber seals. The system operated correctly.

45.000 Delivery Interval

Example 1 (devices with a single layer coating): the amount of limestone was considerable and compromised device use. The adhesion of the limestone on the heating element and the boiler body was such that it could not be removed with water alone. The system was no longer operational.

Example 2 (devices with multi-layer coating): the amount of limestone increased compared to the test after the 30.000 delivery interval, above all on the heating element and on the boiler body, however, without compromising system operation. A larger amount of limestone was detected in all inspection points. In various areas, where limestone was present, it was easily removed with water, showing the original surface; the valve orifices were clear. There were no signs of limestone on pistons and rubber seals. The system operated correctly.

65.000 Delivery Interval

Example 2 (devices with multi-layer coating): the amount of limestone increased compared to the test after the 45.000 delivery interval, above all on the heating element and on the boiler body, however, without compromising system operation. A larger amount of limestone was detected in all inspection points. In various areas, where limestone was present, it was easily removed with water, showing the original surface; the valve orifices were clear. There were no signs of limestone on pistons and rubber seals. The system operated correctly.

Since the tests were considered sufficiently thorough, they were suspended. The experiments demonstrated that a coating of the SiOxCyHzNw type, in both the single layer of the SiOx formula (where x=2) and the silicone multilayer, obtained using the PECVD technique, were able to increase the operational capacity of the water delivery system, demonstrating their efficient anti-limestone treatment. Moreover, they possess the added advantage of containing no heavy metals that can be released in the water.

It was also noted that the systems that were pickled, shot blasted or degreased before the application of the coating according to the present invention, show identical behaviour.

According to the previous descriptions it can be clearly seen that the device for thermohydraulic applications according to the invention, as well as the method for obtaining said devices, achieve the tasks and aims as predetermined.

Examples of devices for thermohydraulic applications according to the present invention include delivery pipes, elements, valves, boilers and similar components. These devices are advantageously applied in systems such as: systems for producing hot water or steam for hot beverages in automatic and semi-automatic machines, both commercial and domestic; household appliances such as irons, humidifiers, kettles, dish-washers, washing machines; floor washers and similar equipment using hot water or steam, both domestic and industrial; systems wherein the hot water or steam is used for personal hygiene; water heating systems for industrial use.

Moreover, it has been found that the use of the above-mentioned coating decreases the realease of heavy metals. In particular, tests were carried out using a boiler made of brass alloy treated and not-treated according to the above-described procedure and then measuring the concentration of metals release into the water according to the following procedure.

a) The boiler was filled with 25 cm³ of bi-distilled water and then closed;

b) The water was heated at 90° C. for 2 hours using a heating element controlled so as to maintain the water temperature at 90° C.;

c) Next day water was added to compensate the evaporation and step b) was repeated;

d) The test was repeated up to a total of 80 hours of heating treatment;

e) Water was added to restore the initial volume and then analysys to determine metal content was carried out. The results, for both the treated and not-treated boils are reported below.

Test results (metal content in mg/l)

Cu: not-treated 0.436; treated 0.072

Pb: not-treated 1.027; treated 0.079

Fe: not-treated 0.001; treated 0.00083

Zn: not-treated 2.61; treated 1.073

Mn: not-treated 0.00083; treated 0.00026

Ba: not-treated 0.0038; treated 0.0012

Thus the results show that the method of the invention substantially decrease the release of metals into the water. This is particularly important in case water is for drinking or human use purposes.

According to the aforesaid description, other characteristics, modifications, or improvements may be applied as they are within the scope of the average technician skilled in the art. Said characteristics, modifications, or improvements, are therefore to be considered as an integral part of the present invention. Practically speaking, all materials used, as well as all contingent dimensions and shapes/forms can be of any kind whatsoever, according to requirements and the technical state of the art.

1-18. (canceled)

19. A device for thermohydraulic applications, comprising:
at least one portion of a surface arranged to be in contact with water, said at least one surface being coated with a film comprising at least one layer of a material formed by a plasma phase polymerization of one or more monomers containing silicone.

20. The device of claim 19, wherein said monomers containing silicone are selected from the group consisting of:
hexamethyldisiloxane, 3-glycidoxypropyl trimethyl-silane, tetramethylsilane, tetraethoxysilane, phenyl-trimethoxysilane, dimethoxymethylphenylsilane, tetraethoxysilane, 3-metacryloxypropyltrimethoxy-silane, triethoxy vinylsilane, octamethylcyclotetra-silane, methyltriethoxysilane, diethoxymethylphenyl-silane, tris(2-methoxyethoxy)vinyl-silane phenyltriethoxysilane, dimethoxydiphenylsilane, tetramethyldisilazane, hexamethyldisilazane, dietoxymethyl-silane, ethyltrimethoxysilane, tetramethoxysilane, methyltrimethoxysilane, dimethoxydimethylsilane, tetramethyldisiloxane, tetramethylethoxysilane, methyltrimethoxysilane, dimethyldimethoxysilane, trimethylmethoxysilane, tetraethylsilane and silane.

21. The device of claim 19, wherein said material comprises SiOₓC_{y}H_{z}N_{w},
where 0.1≦x≦10, 0≦y≦10, 0≦z≦10, and 0≦w≦10.

22. The device of claim 21, wherein said film comprises a plurality of layers of material each having different compositions applied by a plasma phase polymerization of one or more monomers containing silicone.

23. The device of claim 22, wherein said film comprises a first layer comprising SiOₓ where x=2, and a second layer comprising SiOₓC_{y}H_{z}N_{w}.

24. The device of claim 23, wherein said layer of material applied by said plasma phase polymerization has a thickness between 0.01 and 10 μm.

25. The device of claim 24, wherein said monomers containing silicone comprise gaseous organosilicone monomers in pressure conditions between 0.01 and 100 Pa.

26. A thermohydraulic system comprising one or more devices according to claim 19.

27. The thermohydraulic system of claim 26, wherein the system is selected from the group consisting of: commercial and domestic systems for producing hot water or steam for hot beverages in automatic and semi-automatic machines; domestic and industrial appliances including irons, humidifiers, kettles, dish-washers, washing machines, and floor washers using hot water or steam; personal hygiene systems in which the hot water or steam is used; and industrial water heating systems.

28. A method for providing a device with improved water softening properties for thermohydraulic applications, the method comprising:
a) positioning the device within a vacuum chamber;
b) bringing the vacuum chamber to a pressure condition ranging between 0.01 and 100 Pa;
c) introducing a first gaseous mixture comprising at least one monomer comprising silicone into said vacuum chamber;
d) bringing said monomer containing silicone to a plasma state by using an electromagnetic wave; and
e) maintaining ionisation conditions for a period of time sufficient to permit the application of a layer of polymer comprising silicone on at least one portion of a surface of said device.

29. The method of claim 28, further comprising selecting said monomers containing silicone from the group consisting of: hexamethyldisiloxane (HMDSO), tetramethylsilane (TMS), tetraethoxysilane (TEOS), tetramethyldisilazane (TMDS), tetramethylethoxysilane (TMOS), methyltrimethoxysilane (MTMOS), dimethyldimethoxysilane (DMDMOS), trimethylmethoxysilane (TMMOS), tetraethyl silane (TES), and silane.

30. The method of claim 28, wherein said first gaseous mixture comprises oxygen.

31. The method of claim 30, further comprising plasma grafting at least one portion of the surface of said device to provide a surface pre-treatment thereon.

32. The method of claim 31, wherein said steps from c) to e) provide for use of a first gaseous mixture and a successive second gaseous mixture each having a different composition.

33. The method of claim 32, wherein said first and said successive second gaseous mixtures comprise the same components but in differing percentages.

34. A device for thermohydraulic applications produced by the method of claim 28.

35. A thermohydraulic system comprising one or more devices according to claim 34.

36. The thermohydraulic system of claim 35, wherein the system is selected from the group consisting of: commercial and domestic systems for producing hot water or steam for hot beverages in automatic and semi-automatic machines; domestic and industrial appliances including irons, humidifiers, kettles, dish-washers, washing machines, and floor washers using hot water or steam; personal hygiene systems in which the hot water or steam is used; and industrial water heating systems.
